(19) United States
(12) Patent Application Publication
(10) Pub. No.: US 2025/0129214 A1
(43) Pub. Date: Apr. 24, 2025

(54) POLYIMIDE POLYMER AND COMPOSITION THEREFROM

(71) Applicant: DUK SAN NEOLUX CO., LTD., Cheonan-si (KR)

(72) Inventors: Yeon Joon CHUNG, Cheonan-si (KR); Gwang Sik SONG, Cheonan-si (KR); So Mi LEE, Cheonan-si (KR); Changmin LEE, Cheonan-si (KR); Kyung Soo KIM, Cheonan-si (KR)

(73) Assignee: DUK SAN NEOLUX CO., LTD., Cheonan-si (KR)

(21) Appl. No.: 18/921,903

(22) Filed: Oct. 21, 2024

(30) Foreign Application Priority Data
Oct. 20, 2023 (KR) 10-2023-0141249
Aug. 13, 2024 (KR) 10-2024-0107930

(51) Int. Cl. C08G 73/12; G03F 7/004; G03F 7/038

(52) U.S. Cl. CPC C08G 73/122; G03F 7/0045; G03F 7/0382

(57) ABSTRACT

Provided are a polyimide precursor comprising a reactive end group of Formula Q, a polyimide composition comprising the same and having improved tensile strength and elongation, and a pattern or film or a semiconductor or display device or an electronic device prepared using the same.

### TECHNICAL FIELD

The present disclosure relates to a polyimide precursor, and a polymer composition, which is used for a semiconductor device or display device.

### BACKGROUND

A photolithography process largely consists of a coating step for applying a photoresist composition onto a substrate, an exposure step for forming a pattern on a photoresist film using a light source, E-beam, or the like that has passed through a mask; and a development step for removing a specific area of the photoresist film with a pattern engraved on it. The process is performed by adding a heat treatment (baking) step to remove the solvent from the photoresist composition or to cure the film in the middle of each step.

The photolithography process may largely be divided into negative and positive processes, and specifically, be divided into a positive process in which, in the development step, the exposed part reacts chemically with a developer and the reaction product is dissolved and removed; and a negative process in which, conversely, the non-exposed area reacts chemically with a developer, and the reaction product is dissolved and removed. Between these two processes, in the negative process, a photoinitiator, which absorbs light during the exposure step and generates radicals, is used, which enables the exposure with a relatively smaller amount of energy compared to the positive process, and also has an advantage in that it has excellent adhesion to oxide films.

As the positive photosensitive resin composition, which is used in a conventional semiconductor device or display device, the resins of polyimide precursors, polymers, etc., have been used due to their high heat resistance, chemical resistance, and weather resistance, etc., but the development is performed using an alkaline aqueous solution in the development step, which limits the molecular weight of the polymer resin being used, thereby limiting the mechanical properties that can be implemented.

### PRIOR ART DOCUMENT

### Patent Document

(Patent Document 1) KR Patent Application Publication No. 10-2011-0041389
(Patent Document 2) KR Patent Application Publication No. 10-2014-0041371

### SUMMARY

In order to solve the problems of the related art, the present disclosure aims to improve the physical properties by introducing a reactive monomer to the terminal of a polymer formed from a polyimide precursor.

In addition, the present disclosure aims to provide a negative-type photosensitive resin composition using a polymer formed with the polyimide precursor.

In addition, the present disclosure aims to provide a pattern or film formed by the negative photosensitive resin composition, and a semiconductor device or display device prepared using the same.

It is preferable that the polyimide precursor according to the present disclosure includes a reactive end group represented by Formula Q below.

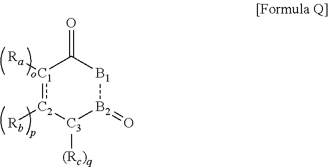

In Formula Q above,
1) Rₐ to R_{c} are each independently hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₁₋₃₀ hydroxyacrylic group; a C₁₋₃₀ hydroxymethacrylic group; a fluorenyl group; a carbonyl group; an ether group; a carboxyl group; or a C₁₋₃₀ alkoxycarbonyl group; or neighboring groups of Rₐ to R_{c} form a ring;
2) C₁ and C₂ are carbon; and the bond connecting C₁ and C₂ is a single bond or double bond,
3) when the bond connecting C₁ and C₂ is a single bond, o and p are each independently an integer of 1 or 2; and when the double dotted line connecting C₁ and C₂ is a double bond, o and p are each independently an integer of 1,
4) C₃ is carbon or a direct bond of C₂—B₂,
5) when C₃ is carbon, q is an integer of 1 or 2,
6) the dotted line connecting B₁ and B₂ is a non-existent bond or single bond,
7) when the dotted line connecting B₁ and B₂ is absent, B₁ is hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a C₁₋₂₀ hydroxyacrylic group; a C₁₋₂₀ hydroxymethacrylic group; a fluorenyl group; a carbonyl group; an ether group; a carboxyl group; or a C₁₋₂₀ alkoxycarbonyl group; and B₂ is carbon connected to a polyimide repeating unit;
8) when the dotted line connecting B₁ and B₂ is a single bond, B₁ is nitrogen connected to a polyimide repeating unit; and B₂ is carbon, and
9) the rings formed by binding between Rₐ to R_{c} and the neighboring groups are each further substituted with at least one substituent selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof, or form a ring between the neighboring substituents.

It is preferable that the negative-type polyimide precursor according to the present disclosure includes a repeating unit selected from the group consisting of Formula 1-1 below, Formula 1-2 below, and a combination thereof.

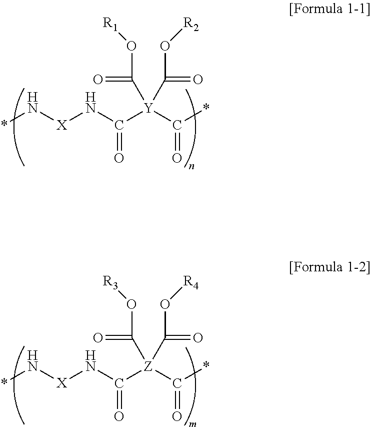

In Formula 1-1 and Formula 1-2 above,
1) * represents a repeating unit or a part in which a bond is connected to the reactive end group represented by Formula Q in claim 1,
2) R₁ and R₄ are Formula 2 below,
3) X is Formula 3 below,
4) m and n are an integer of 1 to 1,000,

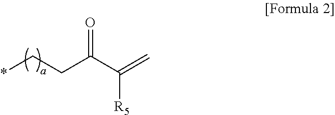

wherein in Formula 2 above,
5) * is a part in which a bond is connected,
6) a is an integer of 1 to 30,
7) R₅ is hydrogen or a methyl group,
8) Y is selected from the group consisting of a C₆₋₃₀ arylene; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkylene group; a C₁₋₂₀ cycloalkylene group; a C₂₋₂₀ alkenylene group; a C₃₋₂₀ cycloalkenylene group; a C₂₋₂₀ alkynylene group; a C₃₋₂₀ cycloalkynylene group; Formula 3 below; and a combination thereof,
9) Z is selected from the group consisting of a C₆₋₃₀ arylene; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkylene group; a C₁₋₂₀ cycloalkylene group; a C₂₋₂₀ alkenylene group; a C₃₋₂₀ cycloalkenylene group; a C₂₋₂₀ alkynylene group; a C₃₋₂₀ cycloalkynylene group; Formula 3 below; and a combination thereof,

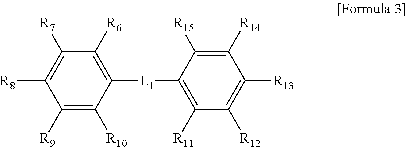

10) L₁ is selected from the group consisting of a single bond, —CH₂—, —CH₂CH₂—, —CH₂OCH₂—, —CH(CH₃)—, —C(CH₃)₂—, —O—, —CH(CF₃)—, —C(CF₃)₂—, —S—, —SO₂—, Si(CH₃)₂—, —C₆H₄—, —OC₆H₄O—, —CO—, —NHCO—, and —COO—,
11) two of R₆ to R₁₅ are parts connected with an amide group of Formula 1-1 or Formula 1-2 above,
12) the remaining R₆ to R₁₅ excluding the connection parts above are each independently hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a fluorenyl group; a carbonyl group; an ether group; a carboxyl group; or a C₁₋₂₀ alkoxycarbonyl group; or neighboring R⁶ and R¹⁵; and R¹⁰ and R¹¹ form a ring, and
13) the rings formed by binding between Y, Z, R₆ to R₁₅, and the neighboring groups are each further substituted with at least one substituent selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof, or form a ring between the neighboring substituents.

The reactive end group represented by Formula Q above may include compounds represented by Formulas Q-1 to Q-6 below.

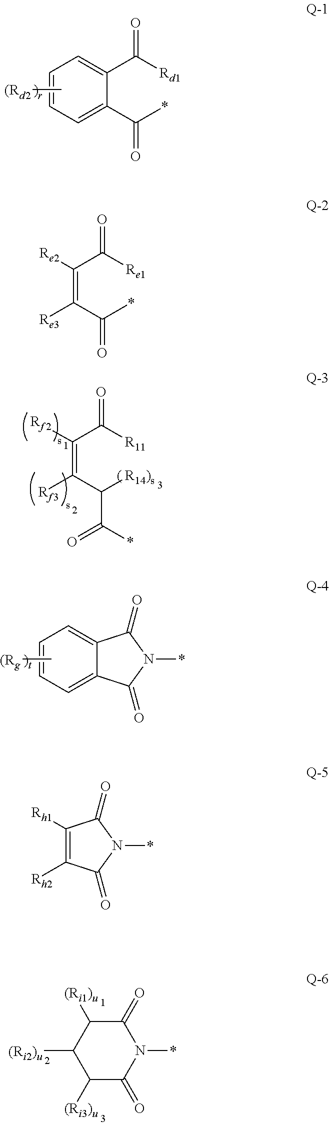

In Formulas Q-1 to Q-6 above,
1) R_{d1}, R_{d2}, Rₑ₁ to Rₑ₃, R_{f1} to R_{f4}, R_{g}, Rₕ₁, Rₕ₂, and Rᵢ₁ to Rᵢ₃ are each independently hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alknyl group; a C₁₋₃₀ alkoxy group; a C₆₋₃₀ aryloxy group; a C₁₋₃₀ hydroxyacrylic group; a C₁₋₃₀ hydroxymethacrylic group; a fluorenyl group; a carbonyl group; an ether group; a carboxyl group; or a C₁₋₃₀ alkoxycarbonyl group,
2) r and t are an integer of 1 to 4,
3) s₁, s₂, and u₁ and u₃ are each independently an integer of 1 or 2, and
4) * is a part in which the bond is connected.

The reactive end group represented by Formula Q above may include compounds represented by Formulas Q-7 to Q-10 below.

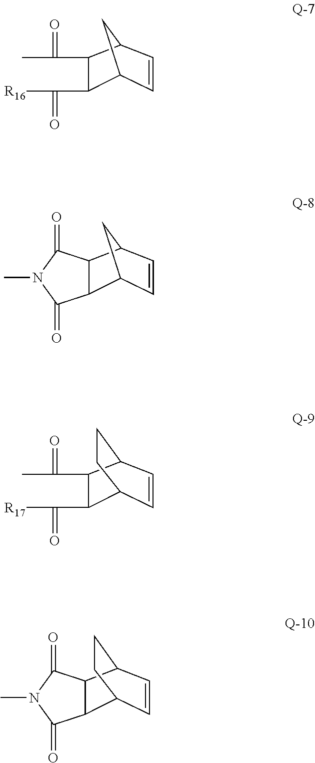

In Formulas Q-7 to Q-10 above,

R₁₆ to R₁₈ are each independently hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a C₁₋₂₀ hydroxyacrylic group; a C₁₋₂₀ hydroxymethacrylic group; a fluorenyl group; a carbonyl group; an ether group; a carboxyl group; or a C₁₋₂₀ alkoxycarbonyl group.

The end of the precursor in a formula selected from Formulas Q-7 to Q-10 above or a formula selected from the group consisting of combinations thereof is connected to by an amide or imide bond.

It is preferable that the polyimide precursor includes at least one among a diamine monomer; a dianhydride monomer; and an anhydride monomer.

It is preferable that the weight average molecular weight of the polyimide precursor is 5,000 g/mol to 40,000 g/mol.

In another specific embodiment of the present disclosure, it is preferable that the polymer composition further includes the polyimide precursor; a photoinitiator; a reactive unsaturated compound; a solvent; and an additive.

It is preferable that the polyimide precursor is contained in an amount of 5 wt % to 50 wt % based on the total amount of the composition.

It is preferable that the photoinitiator is contained in an amount of 0.01 wt % to 10 wt % based on the total amount of the composition.

It is preferable that the reactive unsaturated compound is contained in an amount of 1 wt % to 40 wt % based on the total amount of the composition.

It is preferable that the solvent is contained in an amount of 50 wt % to 95 wt % based on the total amount of the composition.

It is preferable that the additive is contained in an amount of 0.001 wt % to 10 wt % based on the total amount of the composition.

In another specific embodiment of the present disclosure, it is preferable that a pattern or film prepared from the polymer composition is provided.

In another specific embodiment of the present disclosure, it is preferable that a semiconductor device or display device prepared using pattern or film is provided.

In another specific embodiment of the present disclosure, it is preferable that an electronic device which includes the semiconductor device or display device; and a control unit driving the same is provided.

### Advantageous Effects

According to the present disclosure, a polymer composition having improved tensile strength and elongation is produced by introducing a reactive functional group at the end of a polyimide precursor resin, and it can be used in the preparation of a display device or semiconductor device using the same.

### DETAILED DESCRIPTION

Hereinafter, some embodiments of the present disclosure will be described in detail with reference to exemplary drawings. In adding reference numerals to components of each drawing, the same components may have the same reference numerals as far as possible even though they are indicated in different drawings.

When it is determined that a detailed description of a related known constitution or function may obscure the gist of the present disclosure in describing the present disclosure, the detailed description thereof may be omitted. When the expressions “includes”, “has”, “consisting of”, etc. mentioned in this specification are used, other parts may be added unless “only” is used. When a component is expressed in the singular form, it may include a case in which the plural form is included unless otherwise explicitly stated.

In addition, in describing the components of the present disclosure, terms such as first, second, A, B, (a), (b), etc. may be used. Such terms are only for distinguishing the components from other components, and the essence, order, sequence, number, or etc. of the relevant components are not limited by the terms.

In the description of the positional relationship of the components, when two or more components are described as being “connected”, “linked”, or “fused”, etc., the two or more components may be directly “connected”, “linked”, or “fused”, but it should be understood that the two or more components may also be “connected”, “linked”, or “fused” by way of a further “interposition” of a different component. Here, the different component may be included in any one or more of the two or more components that are to be “connected”, “linked”, or “fused” to each other.

In addition, when a component such as a layer, a film, a region, a plate, or etc. is described to be “on top” or “on” of another component, it should be understood that this may not only include a case where the component is “immediately on top of” another component, but also include a case where another component is disposed therebetween. In contrast, it should be understood that when a component is described to be “immediately on top of” another part, this may mean that there is not another part disposed therebetween.

In the description of the temporal flow relationship relating to the components, the operation method, or the preparation method, for example, when the temporal precedence or flow precedence is described by way of “after”, “subsequently”, “thereafter”, “before”, etc., it may also include cases where the flow is not continuous unless terms such as “immediately” or “directly” are used.

Meanwhile, when the reference is made to numerical values or corresponding information for components, numerical values or corresponding information may be interpreted as including an error range that may occur due to various factors (e.g., process factors, internal or external shocks, noise, etc.) even if a separate explicit description is not present.

The terms used in this specification and the appended claims should not be construed as being limited to their ordinary or dictionary meanings, and the present disclosure should be interpreted in a meaning and concept consistent with the technical ideas of the disclosure, based on the principle that the inventor may appropriately define the concept of the term to best explain his invention.

As used herein, the term “halo” or “halogen” includes fluorine (F), chlorine (Cl), bromine (Br), and iodine (I) unless otherwise specified.

As used herein, the term “alkyl” or “alkyl group” refers to a radical of saturated aliphatic functional groups having 1 to 60 carbons linked by a single bond unless otherwise specified, and including a linear chain alkyl group, a branched chain alkyl group, a cycloalkyl (alicyclic) group, an alkyl-substituted cycloalkyl group, and a cycloalkyl-substituted alkyl group.

As used herein, the term “haloalkyl group” or “halogenalkyl group” refers to an alkyl group in which a halogen is substituted unless otherwise specified.

As used herein, the term “alkenyl” or “alkynyl”, unless otherwise specified, has a double bond or triple bond, respectively, includes a linear or branched chain group, and has 2 to 60 carbon atoms, but is not limited thereto.

As used herein, the term “cycloalkyl” refers to alkyl which forms a ring having 3 to 60 carbon atoms unless otherwise specified, but is not limited thereto.

As used herein, the term “alkoxy group” or “alkyloxy group” refers to an alkyl group to which an oxygen radical is bonded, and has 1 to 60 carbon atoms unless otherwise specified, but is not limited thereto.

As used herein, the term “alkenoxyl group”, “alkenoxy group”, “alkenyloxyl group”, or “alkenyloxy group” refers to an alkenyl group to which an oxygen radical is attached, and has 2 to 60 carbon atoms unless otherwise specified, but is not limited thereto.

As used herein, the term “aryl group” and “arylene group” each have 6 to 60 carbon atoms unless otherwise specified, but are not limited thereto. The aryl group or arylene group in this application includes monocyclic compounds, ring assemblies, multiple fused cyclic compounds, etc. For example, the aryl group may include a phenyl group, a monovalent functional group of biphenyl, a monovalent functional group of naphthalene, a fluorenyl group, and a substituted fluorenyl group, and the arylene group may include a fluorenylene group and a substituted fluorenylene group.

As used herein, the term “ring assemblies” means that two or more ring systems (monocyclic or fused ring systems) are directly connected to each other through a single bond or double bond, and the number of direct links between such rings is one less than the total number of ring systems contained in the compound. In the ring assemblies, the same or different ring systems may be directly connected to each other through a single bond or double bond.

As used herein, since the aryl group includes ring assemblies, the aryl group includes biphenyl and terphenyl in which a benzene ring, which is a single aromatic ring, is connected by a single bond. In addition, since the aryl group also includes a compound in which an aromatic ring system fused to an aromatic single ring is connected by a single bond, it also includes, for example, a compound in which a benzene ring, which is an aromatic single ring, and fluorine, which is a fused aromatic ring system, are linked by a single bond.

As used herein, the term “multiple fused ring systems” refers to a fused ring form in which at least two atoms are shared, and it includes a form in which ring systems of two or more hydrocarbons are fused, a form in which at least one heterocyclic system including at least one heteroatom is fused, etc. Such multiple fused ring systems may be an aromatic ring, a heteroaromatic ring, an aliphatic ring, or a combination of these rings. For example, in the case of an aryl group, it may be a naphthalenyl group, a phenanthrenyl group, a fluorenyl group, etc., but is not limited thereto.

As used herein, the term “a spiro compound” has “a spiro union”, and the spiro union refers to a linkage in which two rings are formed by sharing only one atom. At this time, the atom shared by the two rings is called a “spiro atom”, and they are each called “monospiro-”, “dispiro-”, and “trispiro-” compounds depending on the number of spiro atoms included in a compound.

As used herein, the terms “fluorenyl group”, “fluorenylene group”, and “fluorenetriyl group” refer to a monovalent, divalent, or trivalent functional group in which R, R′, R″, and R′″ are all hydrogen in the following structures, respectively, unless otherwise specified, “substituted fluorenyl group”, “substituted fluorenylene group”, or “substituted fluorenetriyl group” means that at least one of the substituents R, R′, R″, and R′″ is a substituent other than hydrogen, and cases where R and R′ are bound to each other to form a spiro compound together with carbon to which they are linked are included. In this specification, all of the fluorenyl group, the fluorenylene group, and the fluorenetriyl group may also be referred to as a fluorene group regardless of valences such as monovalent, divalent, trivalent, etc.

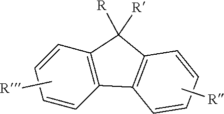

In addition, R, R′, R″, and R′″ may each independently be an alkyl group having 1 to 20 carbon atoms, an alkenyl group having 1 to 20 carbon atoms, an aryl group having 6 to 30 carbon atoms, and a heterocyclic group having 2 to 30 carbon atoms and, for example, the aryl group may be phenyl, biphenyl, naphthalene, anthracene, or phenanthrene, and the heterocyclic group may be pyrrole, furan, thiophene, pyrazole, imidazole, triazole, pyridine, pyrimidine, pyridazine, pyrazine, triazine, indole, benzofuran, quinazoline, or quinoxaline. For example, the substituted fluorenyl group and the fluorenylene group may each be a monovalent functional group or divalent functional group of 9,9-dimethylfluorene, 9,9-diphenylfluorene, and 9,9′-spirobi[9H-fluorene].

As used herein, the term “heterocyclic group” includes not only an aromatic ring such as “heteroaryl group” or “heteroarylene group”, but also a non-aromatic ring, and refers to a ring having 2 to 60 carbon atoms each including one or more heteroatoms unless otherwise specified, but is not limited thereto. As used herein, the term “heteroatom” refers to N, O, S, P, or Si unless otherwise specified, and the heterocyclic group refers to a monocyclic group including a heteroatom, ring assemblies, multiple fused ring systems, spiro compounds, etc.

For example, the “heterocyclic group” may also include a compound including a heteroatom group such as SO₂, P=O, etc. such as the compound shown below, instead of carbon that forms a ring.

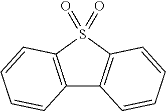 [SMILES: O=S1(=O)c2ccccc2-c2ccccc21]

As used herein, the term “ring” includes monocyclic and polycyclic rings, includes heterocycles containing at least one heteroatom as well as hydrocarbon rings, and includes aromatic and non-aromatic rings.

As used herein, the term “polycyclic” includes ring assemblies such as biphenyl, terphenyl, etc., multiple fused ring systems, and spiro compounds, includes non-aromatic as well as aromatic compounds, and includes heterocycles containing at least one heteroatom as well as hydrocarbon rings.

As used herein, the term “alicyclic group” refers to cyclic hydrocarbons other than aromatic hydrocarbons, includes monocyclic compounds, ring assemblies, multiple fused ring systems, spiro compounds, etc., and refers to a ring having 3 to 60 carbon atoms unless otherwise specified, but is not limited thereto. For example, even when benzene, which is an aromatic ring, and cyclohexane, which is a non-aromatic ring, are fused, the alicyclic group corresponds to an aliphatic ring.

In addition, when prefixes are named consecutively, it means that the substituents are listed in the order they are described. For example, in the case of an arylalkoxy group, it means an alkoxy group substituted with an aryl group, in the case of an alkoxycarbonyl group, it means a carbonyl group substituted with an alkoxy group, and further in the case of an arylcarbonyl alkenyl group, it means an alkenyl group substituted with an arylcarbonyl group, wherein the arylcarbonyl group is a carbonyl group substituted with an aryl group.

Additionally, unless otherwise specified, the term “substituted” in the expression “substituted or unsubstituted” as used herein refers to a substitution with one or more substituents selected from the group consisting of deuterium, a halogen, an amino group, a nitrile group, a nitro group, a C₁₋₃₀ alkyl group, a C₁₋₃₀ alkoxy group, a C₁₋₃₀ alkylamine group, a C₁₋₃₀ alkylthiophene group, a C₆₋₃₀ arylthiophene group, a C₂₋₃₀ alkenyl group, a C₂₋₃₀ alkynyl group, a C₃₋₃₀ cycloalkyl group, a C₆₋₃₀ aryl group, a C₆₋₃₀ aryl group substituted with deuterium, a C₈₋₃₀ arylalkenyl group, a silane group, a boron group, a germanium group, and a C₂₋₃₀ heterocyclic group containing at least one heteroatom selected from the group consisting of O, N, S, Si, and P, but is not limited to these substituents.

Although the “names of functional groups” corresponding to the aryl group, arylene group, heterocyclic group, etc. exemplified as examples of each symbol and a substituent thereof in this application may be described as “names of the functional groups reflecting their valences”, they may also be described as the “names of their parent compounds”. For example, in the case of “phenanthrene”, which is a type of an aryl group, the names of the groups may also be described such that the monovalent “group” is divided and described as “phenanthryl (group)”, and the divalent “group” is divided and described as “phenanthrylene (group)”, etc., but may also be described as “phenanthrene”, which is the name of its parent compound regardless of its valence.

Similarly, in the case of pyrimidine as well, it may be described as “pyrimidine” regardless of its valence, or it may also be described as the “name of the group” of the relevant valence such as pyrimidinyl (group) in the case of monovalent and pyrimidinylene (group) in the case of divalent. Therefore, when the type of a substituent in this application is described as the name of its parent compound, it may refer to an n-valent “group” formed by detachment of a hydrogen atom bonded to a carbon atom and/or hetero atom of its parent compound.

In addition, in describing the names of the compounds or the substituents in this specification, the numbers, alphabets, etc. indicating positions may be omitted. For example, pyrido[4,3-d]pyrimidine may be described as pyridopyrimidine, benzofuro[2,3-d]pyrimidine may be described as benzofuropyrimidine, and 9,9-dimethyl-9H-fluorene may be described as dimethylfluorene. Therefore, both benzo[g]quinoxaline and benzo[f]quinoxaline may be described as benzoquinoxaline.

In addition, unless there is an explicit description, the formulas used in this application are applied in the same manner as in the definition of substituents by the exponent definition of the formula below.

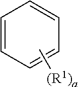

In particular, when a is an integer of 0, it means that the substituent R1 is not present, that is, when a is 0, it means that hydrogen is bonded to all carbons that form a benzene ring, and at this time, the indication of hydrogen bonded to carbons may be omitted, and the formula or compound may be described. In addition, when a is an integer of 1, one substituent R¹ may be bonded to any one of carbons forming a benzene ring, when a is an integer of 2 or 3, it may be bonded, for example, as shown below, even when a is an integer of 4 to 6, it may be bonded to carbons of a benzene ring in a similar manner, and when a is an integer of 2 or more, R¹ may be the same as or different from each other.

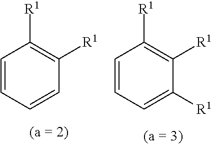

Unless otherwise specified in the present application, forming a ring means that adjacent groups bind to one another to form a single ring or multiple fused rings, and the single ring and the formed multiple fused rings may include a heterocycle containing at least one heteroatom as well as a hydrocarbon ring, and include aromatic and non-aromatic rings.

In addition, unless otherwise specified in the present specification, when indicating a condensed ring, the number in “number-condensed ring” indicates the number of rings to be condensed. For example, a form in which three rings are condensed with one another (e.g., anthracene, phenanthrene, benzoquinazoline, etc.) may be expressed as a 3-condensed ring.

Meanwhile, as used herein, the term “bridged bicyclic compound” refers to a compound in which two rings share 3 or more atoms to form a ring unless otherwise specified. At this time, the shared atoms may include carbon or a hetero atom.

Hereinafter, embodiments of the present disclosure will be described in detail. However, these embodiments are provided for illustrative purposes, and the present disclosure is not limited thereby, and the present disclosure is only defined by the scope of the claims to be described later.

It is preferable that the polyimide precursor according to an embodiment of the present disclosure or a polymer including a polyimide precursor is of negative type.

It is preferable that the polyimide precursor according to one embodiment of the present disclosure is a photosensitive resin composition.

The negative photosensitive resin composition may be used to prepare an insulating film, a surface protection film, and a redistribution layer of a semiconductor device; and a pixel defining layer (PDL) of a display device.

In preparing the positive photosensitive resin composition according to one embodiment of the present disclosure for application in a semiconductor device or display device, the following additives may be additionally included.

As an additive that may be added according to one embodiment of the present disclosure, a surface leveling agent may be additionally included to make the thickness of the coating film constant when coating the substrate. In order to uniformly coat according to the characteristics of the substrate surface, a surfactant may be additionally included, and in order to control the adhesive strength to the substrate surface, a silane-based coupling agent may be additionally included. A crosslinking agent may be additionally included to strengthen the binding between polymer molecules during the heat treatment step.

The components constituting a positive-type photosensitive resin composition are as follows.

### (1) Polyimide Precursor

The patterning resin according to one embodiment of the present disclosure may include a polyimide precursor.

The polyimide precursor refers to a resin including an amic acid copolymer that can be processed into a polyimide polymer through chemical or thermal treatment, and a polyimide polymer that has undergone chemical or thermal treatment.

The polyimide precursor may be contained in an amount of 5 wt % to 50 wt %, preferably 10 wt % to 40 wt %, based on the total amount of the polyimide precursor composition.

The weight average molecular weight of the polyimide precursor may be 5,000 g/mol to 40,000 g/mol, preferably 5,000 g/mol to 35,000 g/mol, and more preferably 6,000 g/mol to 25,000 g/mol.

It is preferable that the polyimide precursor includes a reactive group represented by the following Formula Q at the end group.

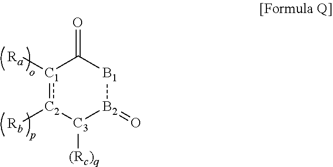

In Formula 1 above,
1) Rₐ to R_{c} are each independently hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₁₋₃₀ hydroxyacrylic group; a C₁₋₃₀ hydroxymethacrylic group; a fluorenyl group; a carbonyl group; an ether group; a carboxyl group; or a C₁₋₃₀ alkoxycarbonyl group; or neighboring groups of Rₐ to R_{c} form a ring;
2) C₁ and C₂ are carbon; and the bond connecting C₁ and C₂ is a single bond or double bond,
3) when the bond connecting C₁ and C₂ is a single bond, o and p are each independently an integer of 1 or 2; and when the double dotted line connecting C₁ and C₂ is a double bond, o and p are each independently an integer of 1,
4) C₃ is carbon or a direct bond of C₂—B₂,
5) when C₃ is carbon, q is an integer of 1 or 2,
6) the dotted line connecting B₁ and B₂ is a non-existent bond or single bond,
7) when the dotted line connecting B₁ and B₂ is absent, B₁ is hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a C₁₋₂₀ hydroxyacrylic group; a C₁₋₂₀ hydroxymethacrylic group; a fluorenyl group; a carbonyl group; an ether group; a carboxyl group; or a C₁₋₂₀ alkoxycarbonyl group; and B₂ is carbon connected to a polyimide repeating unit;
8) when the dotted line connecting B₁ and B₂ is a single bond, B₁ is nitrogen connected to a polyimide repeating unit; and B₂ is carbon, and
9) the rings formed by binding between Rₐ to R_{c} and the neighboring groups are each further substituted with at least one substituent selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof; or form a ring between the neighboring substituents.

It is preferable that the polyimide precursor includes a repeating unit selected from the group consisting of Formula 1-1 below, Formula 1-2 below, and a combination thereof.

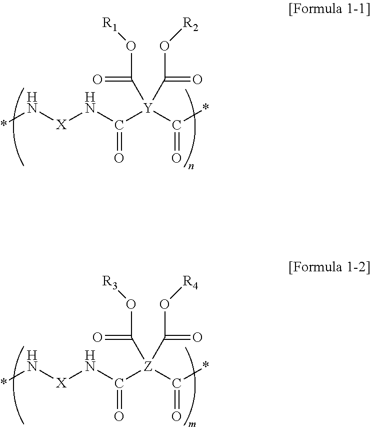

In Formula 1-1 and Formula 1-2 above,
1) * represents a repeating unit or a part in which a bond is connected to the reactive end group represented by Formula Q in claim 1,
2) R₁ and R₄ are Formula 2 below,
3) X is Formula 3 below,
4) m and n are an integer of 1 to 1,000,

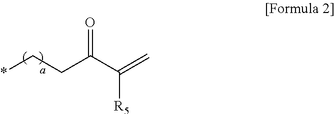

wherein in Formula 2 above,
5) * is a part in which a bond is connected,
6) a is an integer of 1 to 30,
7) R₅ is hydrogen or a methyl group,
8) Y is selected from the group consisting of a C₆₋₃₀ arylene; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkylene group; a C₁₋₂₀ cycloalkylene group; a C₂₋₂₀ alkenylene group; a C₃₋₂₀ cycloalkenylene group; a C₂₋₂₀ alkynylene group; a C₃₋₂₀ cycloalkynylene group; Formula 3 below; and a combination thereof,
9) Z is selected from the group consisting of a C₆₋₃₀ arylene; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkylene group; a C₁₋₂₀ cycloalkylene group; a C₂₋₂₀ alkenylene group; a C₃₋₂₀ cycloalkenylene group; a C₂₋₂₀ alkynylene group; a C₃₋₂₀ cycloalkynylene group; Formula 3 below; and a combination thereof,

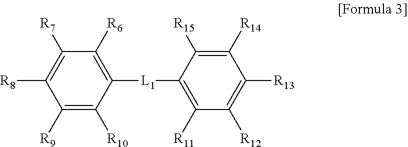

10) L₁ is selected from the group consisting of a single bond, —CH₂—, —CH₂CH₂—, —CH₂OCH₂—, —CH(CH₃)—, —C(CH₃)₂—, —O—, —CH(CF₃)—, —C(CF₃)₂—, —S—, —SO₂—, Si(CH₃)₂—, —C₆H₄—, —OC₆H₄O—, —CO—, —NHCO—, and —COO—,
11) two of R₆ to R₁₅ are parts connected with an amide group of Formula 1-1 or Formula 1-2 above,
12) the remaining R₆ to R₁₅ excluding the connection parts above are each independently hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a fluorenyl group; a carbonyl group; an ether group; a carboxyl group; or a C₁₋₂₀ alkoxycarbonyl group; or neighboring R⁶ and R¹⁵; and R¹⁰ and R¹¹ form a ring, and
13) the rings formed by binding between Y, Z, R₆ to R₁₅, and the neighboring groups are each further substituted with at least one substituent selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group including at least one heteroatom among O, N, S, Si, and P; a C₃₋₃₀ alicyclic group; a C₇₋₃₀ arylalkyl group; a C₈₋₃₀ arylalkenyl group; and a combination thereof, or form a ring between the neighboring substituents.

The polyimide precursor may include at least one among a diamine monomer; a dianhydride monomer; and an anhydride monomer.

It is preferable that the diamine monomer includes at least one selected from the group consisting of 2,2′-bis(3-amino-4-hydroxyphenyl) hexafluoropropane, 2,2′-bis(3-amino-4-hydroxyphenyl)propane, 3,3′-hydroxydihydroxybenzidine, 3,3′-dimethylbenzidine, 2,2′-bis(4-aminophenoxy)phenylpropane, 2,2′-bis(trifluoromethyl)benzidine, 9,9′-bis(3-fluoro-4-aminophenyl)fluorene, 9,9′-bis(4-aminophenyl)fluorene, 2,2′-bis(trifluoromethyl)-4,4′-diaminodiphenylether, 2,2′-bis[4-(4-aminophenoxy)phenyl]hexafluoropropane, 1,3-bis(4-aminophenoxy)benzene, 1,4-bis(4-aminophenoxy)benzene, 2,2′-dimethyl-[1,1′-biphenyl]-4,4′-diamine, 4,4′-bis(4-aminophenoxy)biphenyl, 1,3-bis(3-aminophenoxy)benzene, 2,2′-bis(3-amino-4-hydroxyphenyl)propane, 3,4′-oxydianiline, 9,9′-dimethyl-9H-fluoren-2,7-diamine, 4-aminobenzoic acid-4-aminophenylester, [4-(4-aminobenzoyl)oxyphenyl]4-aminobenzoate, 3,3′,5,5′-tetramethylbenzidine, bis(4-aminophenyl)terephthalate, 4,4′-bis(3-aminophenoxy)biphenyl, N,N′—[[2,2,2-trifluoro-1-(trifluoromethyl)ethylidine]bis(6-hydroxy-3,1-phenylene)bis[3-amino-benzoamide], 2,2′-bis(4-aminophenyl)hexafluoropropane, 4,4′-diaminobenzoanilide, O-tolidine, 4,4′-diaminodiphenylsulfone, and a combination thereof.

It is preferable that the dianhydride monomer includes at least one selected from the group consisting of 4,4′-oxydiphthalic anhydride, 3,3,4,4-biphenyltetracarboxylic dianhydride, pyromellitic acid dianhydride, 4,4′-biphthalic anhydride, 4,4′-(hexafluoroisopropylidene)diphthalic anhydride, 3,3′,4,4′-benzophenonetetracarboxyl dianhydride, 3,3′,4,4′-biphenyltetracarboxyl dianhydride, 2,3,3′,4′-biphenyltetracarboxyl dianhydride, 2,3,3′,4′-tetracarboxydiphenyloxide dianhydride, 1,2,4,5-cyclohexanetetracarboxyl dianhydride, 1,2,3,4-cyclobutanetetracarboxyl dianhydride, 9,9-bis(3,4-dicarboxyphenyl)fluorene dianhydride, bis[3,4-dicarboxylic anhydridephenyl]terephthalate, 1,4-phenylenebis(1,3-dioxo-1,3-dihydroisobenzofuran)-5-carboxylate, 1,4-bis(3,4-dicarboxyphenoxy)benzene dianhydride, and a combination thereof.

It is preferable that the anhydride monomer includes at least one selected from the group consisting of bicyclo[2.2.2]octa-5-en-2,3-dicarboxylic anhydride, 5-norbornen-2,3-dicarboxylic anhydride, maleic anhydride, phthalic anhydride, citraconic anhydride, succinic anhydride, and a combination thereof.

The reactive end group represented by Formula Q above may include compounds represented by the following Formulas Q-1 to Q-6.

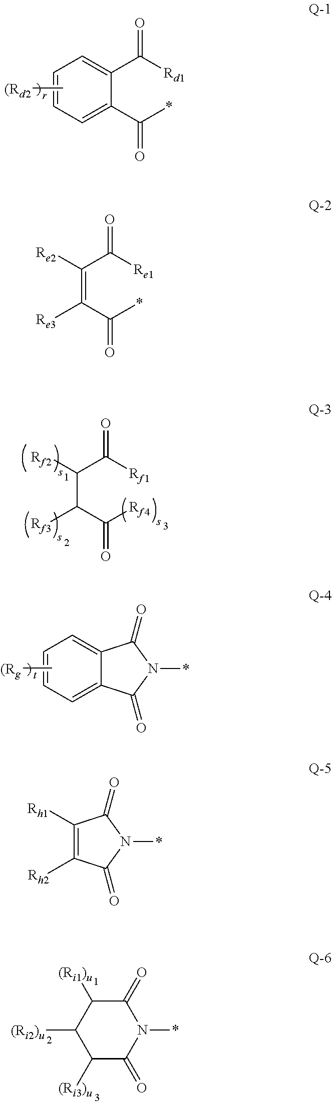

In Formulas Q-1 to Q-6 above,
1) R_{d1}, R_{d2}, Rₑ₁ to Rₑ₃, R_{f1} to R_{f4}, R_{g}, Rₕ₁, Rₕ₂, and Rᵢ₁ to Rᵢ₃ are each independently hydrogen; deuterium; a hydroxy group; a C₆₋₃₀ aryl group; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alknyl group; a C₁₋₃₀ alkoxy group; a C₆₋₃₀ aryloxy group; a C₁₋₃₀ hydroxyacrylic group; a C₁₋₃₀ hydroxymethacrylic group; a fluorenyl group; a carbonyl group; an ether group; a carboxyl group; or a C₁₋₃₀ alkoxycarbonyl group,
2) r and t are an integer of 1 to 4,
3) s₁, s₂, and u₁ and u₃ are each independently an integer of 1 or 2, and
4) * is a part in which the bond is connected.

The reactive end group represented by Formula Q above may include compounds represented by the following Formulas Q-7 to Q-10.

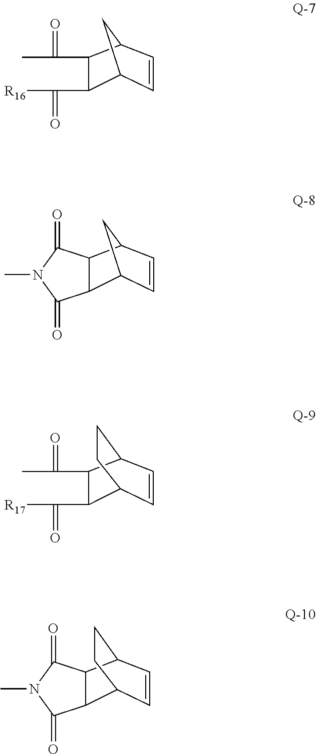

R₁₆ to R₁₈ are each independently hydrogen; deuterium; a hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a C₁₋₂₀ hydroxyacrylic group; a C₁₋₂₀ hydroxymethacrylic group; a fluorenyl group; a carbonyl group; an ether group; a carboxyl group; or a C₁₋₂₀ alkoxycarbonyl group.

One formula selected from Formulas Q-7 to Q-10 above or a formula selected from the group consisting of combinations thereof is connected to the end of the precursor by an amide or imide bond.

It is preferable that the polyimide precursor includes a diamine monomer; a dianhydride monomer; and an anhydride monomer.

The weight average molecular weight of the polyimide precursor resin may be 5,000 g/mol to 40,000 g/mol, preferably 5,000 g/mol to 30,000 g/mol, and more preferably 6,000 g/mol to 25,000 g/mol. When the weight average molecular weight of the resin is within the above-described range, no residue of the exposed layer remains during development, and the loss of film thickness of the non-exposed layer is minimized, and thus a good pattern can be obtained. The polymer may be contained in an amount of 5 wt % to 50 wt %, and more preferably 15 wt % to 45 wt %, based on the total amount of the polymer composition. When the resin is contained within the above-described range, a constant film thickness can be obtained in the coating step, and excellent sensitivity, developability, and adhesion (an adherent property) can be obtained.

### (2) Photoactive Compound

A photoradical initiator should be used in order to implement a negative pattern with photolithography.

The photoinitiator is an initiator generally used in negative-type photosensitive resin compositions, and for example, an acetophenone-based compound, a benzophenone-based compound, a thioxanthone-based compound, a benzoin-based compound, a triazine-based compound, etc. may be used.

Examples of the acetophenone-based compound may include 2,2′-diethoxy acetophenone, 2,2′-dibutoxy acetophenone, 2-hydroxy-2-methylpropiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, etc.

Examples of the benzophenone-based compound may include benzophenone, benzoyl benzoate, methyl benzoyl benzoate, 4-phenyl benzophenone, hydroxy benzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, etc.

Examples of the thioxanthone-based compound may include thioxanthone, 2-chlorothioxanthone, 2-methylthioxanthone, isopropyl thioxanthone, 2,4-diethyl thioxanthone, 2,4-diisopropyl thioxanthone, 2-chlorothioxanthone, etc.

Examples of the benzoin-based compound may include benzoin, benzoin methyl ether, benzoin ethyl ether, benzoin isopropyl ether, benzoin isobutyl ether, benzyldimethyl ketal, etc.

Examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine, 2-biphenyl 4,6-bis(trichloromethyl)-s-triazine, bis(trichloromethyl)-6-styryl-s-triazine, 2-(naphtho-1-yl)-4,6-bis(trichloromethyl)-s-triazine, 2-(4-methoxy-naphtho-1-yl)-4,6-bis(trichloromethyl)-s-triazine, 2-4-trichloromethyl(piperonyl)-6-triazine, 2-4-trichloromethyl(4′-methoxystyryl)-6-triazine, etc.

Examples of the oxime ester-based compound may include 1-[4-(phenylthio)phenyl]-1,2-octanedione-2-(o-benzoyloxime), 1-[({1-[9-ethyl-6-(2-methylbenzoyl)-9H-carbazol-3-yl]ethylidine}amino]oxy]-1-(O-acetyloxime)ethanone, 1-[ethyl-6-{2-methyl-4-(2,2-dimethyl-1,3-dioxolanyl)methoxybenzoyl}-9H-carbazol-3-yl]ethanone, 1-[4-[3-[4-[[2-acetyloxy]ethyl]sulfonyl]-2-methylbenzoyl]-6-[1-[(acetyloxy)imino]ethyl]-9H-carbazol-9-yl]phenyl-1-(O-acetyloxime)octanone, 1-[9-ethyl-6-(2-methyl-4-tetrahydrofuranylmethoxybenzoyl)-9H-carbazol-3-yl]-1-(O-acetyloxime)ethanone, etc.

The photoinitiator may include carbazole-based compounds, diketone-based compounds, sulfonium borate-based compounds, diazo-based compounds, imidazole-based compounds, non-imidazole-based compounds, etc. in addition to the above compounds.

The photoinitiator may include a peroxide-based compound, an azobis-based compound, etc. as radical polymerization initiators.

Examples of the peroxide-based compound may include ketone peroxides such as methyl ethyl ketone peroxide, methyl isobutyl ketone peroxide, cyclohexanone peroxide, methylcyclohexanone peroxide, acetylacetone peroxide, etc.; diacyl peroxides such as isobutyryl peroxide, 2,4-dichlorobenzoyl peroxide, o-methylbenzoyl peroxide, bis-3,5,5-trimethylhexanoyl peroxide, etc.; hydroperoxides such as 2,4,4,-trimethylpentyl-2-hydroperoxide, diisopropylbenzene hydroperoxide, cumene hydroperoxide, t-butyl hydroperoxide, etc.; dialkyl peroxides such as dicumyl peroxide, 2,5-dimethyl-2,5-di(t-butylperoxy)hexane, 1,3-bis(t-butyloxyisopropyl)benzene, t-butylperoxyvalerate n-butyl ester, etc.; alkyl peresters such as 2,4,4-trimethylpentyl peroxyphenoxyacetate, α-cumyl peroxyneodecanoate, t-butyl peroxybenzoate, di-t-butyl peroxytrimethyl adipate, etc.; and percarbonates such as di-3-methoxybutyl peroxydicarbonate, di-2-ethylhexyl peroxydicarbonate, bis-4-t-butylcyclohexyl peroxydicarbonate, diisopropyl peroxydicarbonate, acetylcyclohexylsulfonyl peroxide, t-butyl peroxyaryl carbonate, etc.

Examples of the azobis-based compound may include 1,1′-azobiscyclohexan-1-carbonitrile, 2,2′-azobis(2,4-dimethylvaleronitrile), 2,2,-azobis(methylisobutyrate), 2,2′-azobis(4-methoxy-2,4-dimethylvaleronitrile), α,α′-azobis(isobutylnitrile), 4,4′-azobis(4-cyanovaleric acid), etc.

The photoinitiator may be used together with a photosensitizer that causes a chemical reaction by absorbing light and thus becoming an excited state and then transferring the energy of light. Examples of the photosensitizer may include tetraethylene glycol bis-3-mercaptopropionate, pentaerythritol tetrakis-3-mercaptopropionate, dipentaerythritol tetrakis-3-mercaptopropionate, etc.

The photoinitiator may be contained in an amount of 0.01 wt % to 10 wt %, for example, 0.1 wt % to 5 wt % based on the total amount of the photosensitive resin composition. When the photoinitiator is contained within the above-described range, curing occurs sufficiently during exposure in the pattern forming process so that excellent reliability may be obtained, heat resistance, light resistance, and chemical resistance of the pattern are excellent, resolution and adhesion are also excellent, and a decrease in transmittance due to an unreacted initiator may be prevented.

### (3) Reactive Unsaturated Compound

A reactive unsaturated compound that is absolutely necessary for negative patterns may form a pattern having excellent heat resistance, light resistance, and chemical resistance by causing sufficient polymerization during exposure in the pattern forming process by having an ethylenically unsaturated double bond.

Specific examples of the reactive unsaturated compound may include ethylene glycol diacrylate, ethylene glycol dimethacrylate, diethylene glycol diacrylate, triethylene glycol diacrylate, triethylene glycol dimethacrylate, 1,6-hexanediol diacrylate, 1,6-hexanediol dimethacrylate, pentaerythritol triacrylate, dipentaerythritol pentaacrylate, dipentaerythritol hexaacrylate, bisphenol A epoxy acrylate, ethylene glycol monomethyl ether acrylate, trimethylolpropane triacrylate, tripentaerythritol octaacrylate, 4-hydroxybutyl acrylate, etc.

Examples of commercially available products of the reactive unsaturated compound are as follows.

Examples of a bifunctional ester of (meth)acrylic acid may include Aronix M-210, M-240, M-6200, etc. of Toa Kosei Kagaku Kogyo Co., Ltd.; KAYARAD HDDA, HX-220, R-604, etc. of Nippon Kayaku Co., Ltd; and V-260, V-312, V-335 HP, etc. of Osaka Yuki Kagaku Kogyo Co., Ltd.

Examples of a trifunctional ester of (meth)acrylic acid may include Aronix M-309, M-400, M-405, M-450, M-7100, M-8030, M-8060, etc. of Toa Kosei Kagaku Kogyo Co., Ltd.; KAYARAD TMPTA, DPCA-20, DPCA-60, DPCA-120, etc. of Nippon Kayaku Co., Ltd.; and V-295, V-300, V-360, etc. of Osaka Yuki Kagaku Kogyo Co., Ltd.

The above products may be used alone or used together in combinations of two or more.

The reactive unsaturated compound may be used after treating with an acid anhydride so as to impart more excellent developing properties. The reactive unsaturated compound may be contained in an amount of 1 wt % to 40 wt %, for example, 1 wt % to 20 wt % based on the total amount of the polymer composition. When the reactive unsaturated compound is contained within the above-described range, sufficient curing occurs during exposure in the pattern forming process so that reliability is excellent, heat resistance, light resistance, and chemical resistance of the pattern are excellent, and resolution and adhesion are also excellent.

### (4) Solvent

As the solvent, those materials which are compatible with the polyimide precursor or polymer, the photoactive compound, and the pigments, but do not react with them may be used.

Examples of the solvent include alcohols such as methanol, ethanol, etc.; ethers such as dichloroethyl ether, n-butyl ether, diisoamyl ether, methylphenyl ether, tetrahydrofuran, etc.; glycol ethers such as ethylene glycol monomethyl ether, ethylene glycol monoethyl ether, etc.; cellosolve acetates such as methyl cellosolve acetate, ethyl cellosolve acetate, diethyl cellosolve acetate, etc.; carbitols such as methylethyl carbitol, diethyl carbitol, diethylene glycol monomethyl ether, diethylene glycol monoethyl ether, diethylene glycol dimethyl ether, diethylene glycol methyl ethyl ether, diethylene glycol diethyl ether, etc.; propylene glycol alkyl ether acetates such as propylene glycol methyl ether acetate, propylene glycol propyl ether acetate, etc.; aromatic hydrocarbons such as toluene, xylene, etc.; ketones such as methyl ethyl ketone, cyclohexanone, 4-hydroxy-4-methyl-2-pentanone, methyl-n-propyl ketone, methyl-n-butyl ketone, methyl-n-amyl ketone, 2-heptanone, etc.; saturated aliphatic monocarboxylic acid alkyl esters such as ethyl acetate, n-butyl acetate, isobutyl acetate, etc.; lactic acid esters such as methyl lactate, ethyl lactate, etc.; oxyacetic acid alkyl esters such as methyl oxyacetate, ethyl oxyacetate, butyl oxyacetate, etc.; alkoxy acetate alkyl esters such as methoxy methyl acetate, methoxy ethyl acetate, methoxy butyl acetate, ethoxy methyl acetate, ethoxy ethyl acetate, etc.; 3-oxypropionic acid alkyl esters such as 3-oxy methyl propionate, 3-oxy ethyl propionate, etc.; 3-alkoxy propionic acid alkyl esters such as 3-methoxy methyl propionate, 3-methoxy ethyl propionate, 3-ethoxy ethyl propionate, 3-ethoxy methyl propionate, etc.; 2-oxypropionic acid alkyl esters such as methyl 2-oxypropionate, ethyl 2-oxypropionate, propyl 2-oxypropionate, etc.; 2-alkoxy propionic acid alkyl esters such as 2-methoxy methyl propionate, 2-methoxy ethyl propionate, 2-ethoxy ethyl propionate, 2-ethoxy methyl propionate, etc.; monooxy monocarboxylic acid alkyl esters of 2-oxy-2-methyl propionic acid esters such as 2-oxy-2-methyl methyl propionate, 2-oxy-2-methyl ethyl propionate, etc., and 2-alkoxy-2-methyl propionic acid alkyls such as 2-methoxy-2-methyl methyl propionate, 2-ethoxy-2-methyl ethyl propionate, etc.; esters such as 2-hydroxyethyl propionate, 2-hydroxy-2-methyl ethyl propionate, ethyl hydroxyacetate, 2-hydroxy-3-methyl methyl butanoate, etc.; and ketonic acid esters such as ethyl pyruvate, etc.

Further, high-boiling point solvents such as N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetylacetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and phenyl cellosolve acetate may also be used.

Considering compatibility and reactivity, among the above solvents, glycol ethers such as ethylene glycol monoethyl ether, etc.; ethylene glycol alkyl ether acetates such as ethyl cellosolve acetate, etc.; esters such as ethyl 2-hydroxypropionate, etc.; carbitols such as diethylene glycol monomethyl ether, etc.); and propylene glycol alkyl ether acetates such as propylene glycol methyl ether acetate, propylene glycol propyl ether acetate, etc. may be used.

The solvent may be contained as a balance amount based on the total amount of the photosensitive resin composition, and specifically in an amount of 50 wt % to 95 wt %. When the solvent is contained within the above-described range, the processability when preparing the pattern layer is excellent as the negative-type photosensitive resin composition has an appropriate viscosity.

### (4) Other Additives

In order to prevent stains or spots during application, to improve leveling performance, and to prevent the generation of residues due to non-development, the negative-type polymer composition may further include additives, such as malonic acid; 3-amino-1,2-propanediol; a silane-based coupling agent containing a vinyl group or (meth)acryloxy group; a surface leveling agent; a surfactant; a crosslinker; etc.

For example, the polymer composition may further include a silane-based coupling agent having a reactive substituent such as a vinyl group, a carboxyl group, a methacryloxy group, an isocyanate group, an epoxy group, etc. in order to improve adhesion to a substrate, etc.

Examples of the silane-based coupling agent may include trimethoxysilyl benzoic acid, γ-methacryloxypropyl trimethoxysilane, vinyl triacetoxysilane, vinyl trimethoxysilane, γ-isocyanate propyl triethoxysilane, γ-glycidoxy propyl trimethoxy silane, 3-epoxy cyclohexyl ethyl trimethoxy silane, and silane-based coupling agents of Shinetsu Silicon, which are commercially available under the names KBM-502, KBM-602, KBM-573, KBE-9007N, etc., and these may be used alone or in a mixture of two or more.

The silane-based coupling agent may be contained in an amount of 0.01 parts by weight to 10 parts by weight based on 100 parts by weight of the polymer composition. When the silane-based coupling agent is contained within the above-described range, adhesion, storability, etc. are excellent.

In addition, the photosensitive resin composition may further include a surface leveling agent so as to form a constant film thickness in the coating step, if necessary.

The surface leveling agent to be used may include F-554®, F-556®, F-557®, F-559®, F-560®, F-563®, RS-72-K®, R-40®, R-41®, R-43®, etc. from DIC; Efka® FL3740, Efka® FL3741, Efka® FL3745, Efka® FL3770, etc. from BASF.

The surface leveling agent can be used in an amount of 0.001 to 5 parts by weight per 100 parts by weight of the polymer composition. When the surface leveling agent is included within the above-described range, coating uniformity can be secured and the film can be coated to have a constant thickness.

In addition, the photosensitive resin composition may further include a surfactant to improve coating properties and prevent defects, if necessary.

The surfactant to be used may include those commercially available under the names of: BM-1000®, BM-1100®, etc. from BM Chemie; Megaface F 142D®, Megaface F 172®, Megaface F 173®, Megaface F 183®, etc. from Dainippon Ink Kagaku Kogyo; Fluorad FC-135®, Fluorad FC-170C®, Fluorad FC-430®, Fluorad FC-431®, etc. from Sumitomo 3M; Saffron S-112®, Saffron S-113®, Saffron S-131®, Saffron S-141®, Saffron S-145®, etc. from Asahi Glass; and SH-28PA®, SH-190®, SH-193®, SZ-6032®, SF-8428®, etc. from Toray Silicone.

In addition, the polymer composition may further include a silicone-based surfactant, if necessary.

The silicone-based surfactant to be used may include silicone-based surfactants commercially available under the names of: 5-101, 5-201, 5-301, 5-601, 5-701, 5-801 RS-55, RS-56, etc. from DIC; EFKA® 3030, EFKA® 3034, EFKA®3886, etc. from BASF; 3030, 3085, 3236, etc from AFCONA; and BYK-379, BYK-3550, BYK-3751, BYK-3754, etc. from BYK.

The surfactant may be used in an amount of 0.001 to 5 parts by weight based on 100 parts by weight of the polymer composition. When the surfactant is contained within the above-described range, coating uniformity can be secured, stains do not occur, and wetting to the glass substrate is excellent.

As the crosslinker, 1,4-bis(methoxymethyl)benzene, diethyl sulfate, 3-aminopropyltriethoxysilane, N,N′-methylenebis acrylamide, N,N′-dicyclohexylcarbodiimide, etc. may be used, and these may be used alone or in a mixture of two or more.

The crosslinker may be used in an amount of 0.001 to 5 parts by weight per 100 parts by weight of the polymer composition. When the crosslinker is included within the above-described range, it is advantageous in appropriately imparting physical properties, for example, mechanical properties (e.g., tensile strength) to the cured coating film.

In addition, a certain amount of other additives may be added to the polymer composition within a range that does not impair physical properties.

Hereinafter, Synthesis Examples and Examples according to the present disclosure will be described in detail, but Synthesis Examples and Examples of the present disclosure are not limited thereto.

### Synthesis Example 1

(Solution A) A 500 mL fruit circulation jacket reactor was installed by attaching a stirrer, a nitrogen injection device, a dropping funnel, a temperature controller, and a cooler thereto, charged with 141.87 g of N-methylpyrrolidone (NMP) while filling it with nitrogen. Then, 22.22 g of 3,3′,4,4′-benzophenonetetracarboxylic anhydride was added thereto and the mixture was maintained at 25° C. while stirring. 19.86 g of 4-hydroxybutyl acrylate was added thereto and reacted while slowly adding 11.17 g of pyridine thereto. Thereafter, a solution, in which 35.54 g of N,N′-dicyclohexylcarbodiimide and 71.07 g of N-methylpyrrolidone (NMP) were mixed, was slowly added thereto dropwise and stirred for 3 hours while maintaining the internal temperature of the reactor where the reaction was in progress at −10° C.

(Solution B) A 500 mL fruit circulation jacket reactor was installed by attaching a stirrer, a nitrogen injection device, a dropping funnel, a temperature controller, and a condenser thereto, charged with 62.09 g of N-methylpyrrolidone (NMP) while filling it with nitrogen, and the mixture was maintained at 25° C. while stirring. Then, 15 g of 3,3′-dimethylbenzidine was added thereto and the mixture was stirred until it was completely dissolved, and 0.52 g of phthalic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 2,275 g of distilled water was added thereto dropwise to cause precipitation. The solid obtained here was washed twice with distilled water and then dried under vacuum at 25° C. for 48 hours to obtain copolymerized polyimide precursor powder.

### Synthesis Example 2

(Solution A) A 500 mL fruit circulation jacket reactor was installed by attaching a stirrer, a nitrogen injection device, a dropping funnel, a temperature controller, and a condenser thereto, charged with 141.87 g of N-methylpyrrolidone (NMP) while filling it with nitrogen. Then, 22.22 g of 3,3′,4,4′-benzophenonetetracarboxylic anhydride was added thereto and the mixture was maintained at 25° C. while stirring. 19.86 g of 4-hydroxybutyl acrylate was added thereto and reacted while slowly adding 11.17 g of pyridine thereto. Thereafter, a solution, in which 35.54 g of N,N′-dicyclohexylcarbodiimide and 71.07 g of N-methylpyrrolidone (NMP) were mixed, was slowly added thereto dropwise and stirred for 3 hours while maintaining the internal temperature of the reactor where the reaction was in progress at −10° C.

(Solution B) A 500 mL fruit circulation jacket reactor was installed by attaching a stirrer, a nitrogen injection device, a dropping funnel, a temperature controller, and a condenser thereto, charged with 61.58 g of N-methylpyrrolidone (NMP) while filling it with nitrogen, and the mixture was maintained at 25° C. while stirring. Then, 15 g of 3,3′-dimethylbenzidine was added thereto and the mixture was stirred until it was completely dissolved, and 0.40 g of citraconic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 2,272 g of distilled water was added thereto dropwise to cause precipitation. The solid obtained here was washed twice with distilled water and then dried under vacuum at 25° C. for 48 hours to obtain copolymerized polyimide precursor powder.

### Synthesis Example 3

(Solution A) A 500 mL fruit circulation jacket reactor was installed by attaching a stirrer, a nitrogen injection device, a dropping funnel, a temperature controller, and a condenser thereto, charged with 141.87 g of N-methylpyrrolidone (NMP) while filling it with nitrogen. Then, 22.22 g of 3,3′,4,4′-benzophenonetetracarboxylic anhydride was added thereto and the mixture was maintained at 25° C. while stirring. 19.86 g of 4-hydroxybutyl acrylate was added thereto and reacted while slowly adding 11.17 g of pyridine thereto. Thereafter, a solution, in which 35.53 g of N,N′-dicyclohexylcarbodiimide and 71.07 g of N-methylpyrrolidone (NMP) were mixed, was slowly added thereto dropwise and stirred for 3 hours while maintaining the internal temperature of the reactor where the reaction was in progress at −10° C.

(Solution B) A 500 mL fruit circulation jacket reactor was installed by attaching a stirrer, a nitrogen injection device, a dropping funnel, a temperature controller, and a condenser thereto, charged with 61.61 g of N-methylpyrrolidone (NMP) while filling it with nitrogen, and the mixture was maintained at 25° C. while stirring. Then, 15 g of 3,3′-dimethylbenzidine was added thereto and the mixture was stirred until it was completely dissolved, and 0.40 g of glutaric anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 2,272 g of distilled water was added thereto dropwise to cause precipitation. The solid obtained here was washed twice with distilled water and then dried under vacuum at 25° C. for 48 hours to obtain copolymerized polyimide precursor powder.

### Synthesis Example 4

A 500 mL fruit circulation jacket reactor was installed by attaching a stirrer, a nitrogen injection device, a dropping funnel, a temperature controller, and a condenser thereto, charged with 205.32 g of N-methylpyrrolidone (NMP) while filling it with nitrogen. Then, 22.22 g of 3,3′,4,4′-benzophenonetetracarboxylic anhydride and 0.52 g of phthalic anhydride were added thereto and the mixture was maintained at 25° C. while stirring. 20.37 g of 4-hydroxybutyl acrylate was added thereto and reacted while slowly adding 11.46 g of pyridine thereto. Thereafter, a solution, in which 36.46 g of N,N′-dicyclohexylcarbodiimide and 72.89 g of N-methylpyrrolidone (NMP) were mixed, was slowly added thereto dropwise and stirred for 3 hours while maintaining the internal temperature of the reactor where the reaction was in progress at −10° C. Thereafter, the internal temperature was cooled to −10° C., and 15 g of 3,3′-dimethylbenzidine was added thereto dropwise while stirring for 30 minutes. Then, the temperature was raised to 25° C. over 1 hour, the reaction was maintained for 2 hours, and then 2,305 g of distilled water was added thereto dropwise to cause precipitation. The solid obtained here was washed twice with distilled water and then dried under vacuum at 25° C. for 48 hours to obtain copolymerized polyimide precursor powder.

### Synthesis Example 5

A 500 mL fruit circulation jacket reactor was installed by attaching a stirrer, a nitrogen injection device, a dropping funnel, a temperature controller, and a condenser thereto, charged with 204.81 g of N-methylpyrrolidone (NMP) while filling it with nitrogen. Then, 22.22 g of 3,3′,4,4′-benzophenonetetracarboxylic anhydride and 0.40 g of citraconic anhydride were added thereto and the mixture was maintained at 25° C. while stirring. 20.37 g of 4-hydroxybutyl acrylate was added thereto and reacted while slowly adding 11.45 g of pyridine thereto. Thereafter, a solution, in which 36.45 g of N,N′-dicyclohexylcarbodiimide and 72.89 g of N-methylpyrrolidone (NMP) were mixed, was slowly added thereto dropwise and stirred for 3 hours while maintaining the internal temperature of the reactor where the reaction was in progress at −10° C. Thereafter, the internal temperature was cooled to −10° C., and 15 g of 3,3′-dimethylbenzidine was added thereto dropwise while stirring for 30 minutes. Then, the temperature was raised to 25° C. over 1 hour, the reaction was maintained for 2 hours, and then 2,301 g of distilled water was added thereto dropwise to cause precipitation. The solid obtained here was washed twice with distilled water and then dried under vacuum at 25° C. for 48 hours to obtain copolymerized polyimide precursor powder.

### Synthesis Example 6

A 500 mL fruit circulation jacket reactor was installed by attaching a stirrer, a nitrogen injection device, a dropping funnel, a temperature controller, and a condenser thereto, charged with 204.84 g of N-methylpyrrolidone (NMP) while filling it with nitrogen. Then, 22.22 g of 3,3′,4,4′-benzophenonetetracarboxylic anhydride and 0.40 g of glutaric anhydride were added thereto and the mixture was maintained at 25° C. while stirring. 20.37 g of 4-hydroxybutyl acrylate was added thereto and reacted while slowly adding 11.46 g of pyridine thereto. Thereafter, a solution, in which 36.45 g of N,N′-dicyclohexylcarbodiimide and 72.89 g of N-methylpyrrolidone (NMP) were mixed, was slowly added thereto dropwise and stirred for 3 hours while maintaining the internal temperature of the reactor where the reaction was in progress at −10° C. Thereafter, the internal temperature was cooled to −10° C., and 15 g of 3,3′-dimethylbenzidine was added thereto dropwise while stirring for 30 minutes. Then, the temperature was raised to 25° C. over 1 hour, the reaction was maintained for 2 hours, and then 2,302 g of distilled water was added thereto dropwise to cause precipitation. The solid obtained here was washed twice with distilled water and then dried under vacuum at 25° C. for 48 hours to obtain copolymerized polyimide precursor powder.

### Synthesis Example 7

(Solution A) A 500 mL fruit circulation jacket reactor was installed by attaching a stirrer, a nitrogen injection device, a dropping funnel, a temperature controller, and a condenser thereto, charged with 256.4 g of N-methylpyrrolidone (NMP) while filling it with nitrogen. Then, 22.31 g of 4,4′-oxydiphthalic anhydride and 5.29 g of 3,3′,4,4′-biphenyltetracarboxylic dianhydride were added thereto and the mixture was maintained at 35° C. while stirring. 25.91 g of 4-hydroxybutyl acrylate was added thereto and reacted while slowly adding 29.15 g of pyridine thereto. Thereafter, a solution, in which 37.09 g of N,N′-dicyclohexylcarbodiimide and 74.190 g of γ-butyrolactone were mixed, was slowly added thereto dropwise and stirred for 3 hours while maintaining the internal temperature of the reactor where the reaction was in progress at −10° C.

(Solution B) A 1,000 mL fruit circulation jacket reactor was installed by attaching a stirrer, a nitrogen injection device, a dropping funnel, a temperature controller, and a condenser thereto, charged with 93.11 g of N-methylpyrrolidone (NMP) while filling it with nitrogen, and the mixture was maintained at 25° C. while stirring. Then, 20 g of 4,4′-oxydianiline was added thereto and the mixture was stirred until it was completely dissolved, and 3.28 g of 5-norbornen-2,3-dicarboxylic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 40 g of ethanol was added thereto and maintained for 1 hour while stirring. Then, 1,417 g of ethanol was added to the filtered solution using a filter paper to precipitate a solid. This solid was dissolved in 56.68 g of THE and added dropwise to 6,802 g of distilled water to cause precipitation. The solid obtained here was washed twice with distilled water and then dried under vacuum at 25° C. for 48 hours to obtain copolymerized polyimide precursor powder.

### Synthesis Example 8

(Solution A) A 500 mL fruit circulation jacket reactor was installed by attaching a stirrer, a nitrogen injection device, a dropping funnel, a temperature controller, and a condenser thereto, charged with 258.4 g of N-methylpyrrolidone (NMP) while filling it with nitrogen. Then, 13.94 g of 4,4′-oxydiphthalic anhydride and 13.22 g of 3,3′,4,4′-biphenyltetracarboxylic dianhydride were added thereto and the mixture was maintained at 35° C. while stirring. 25.91 g of 4-hydroxybutyl acrylate was added thereto and reacted while slowly adding 29.15 g of pyridine thereto. Thereafter, a solution, in which 37.09 g of N,N′-dicyclohexylcarbodiimide and 74.190 g of γ-butyrolactone were mixed, was slowly added thereto dropwise and stirred for 3 hours while maintaining the internal temperature of the reactor where the reaction was in progress at −10° C.

(Solution B) A 1,000 mL fruit circulation jacket reactor was installed by attaching a stirrer, a nitrogen injection device, a dropping funnel, a temperature controller, and a condenser thereto, charged with 93.11 g of N-methylpyrrolidone (NMP) while filling it with nitrogen, and the mixture was maintained at 25° C. while stirring. Then, 20 g of 4,4′-oxydianiline was added thereto and the mixture was stirred until it was completely dissolved, and 3.28 g of 5-norbornen-2,3-dicarboxylic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 40 g of ethanol was added thereto and the mixture was stirred for 1 hour, and then 7.6 g of mandelic acid was added thereto and the mixture was stirred for 2 hours. Then, 1,417 g of ethanol was added to the filtered solution using a filter paper to precipitate a solid. This solid was dissolved in 56.68 g of THF and added dropwise to 6,802 g of distilled water to cause precipitation. The solid obtained here was washed twice with distilled water and then dried under vacuum at 25° C. for 48 hours to obtain copolymerized polyimide precursor powder.

### Synthesis Example 9

(Solution A) A 500 mL fruit circulation jacket reactor was installed by attaching a stirrer, a nitrogen injection device, a dropping funnel, a temperature controller, and a condenser thereto, charged with 256.4 g of N-methylpyrrolidone (NMP) while filling it with nitrogen. Then, 5.57 g of 4,4′-oxydiphthalic anhydride and 21.16 g of 3,3′,4,4′-biphenyltetracarboxylic dianhydride were added thereto and the mixture was maintained at 35° C. while stirring. 25.91 g of 4-hydroxybutyl acrylate was added thereto and reacted while slowly adding 29.15 g of pyridine thereto. Thereafter, a solution, in which 37.09 g of N,N′-dicyclohexylcarbodiimide and 74.190 g of γ-butyrolactone were mixed, was slowly added thereto dropwise and stirred for 3 hours while maintaining the internal temperature of the reactor where the reaction was in progress at −10° C.

(Solution B) A 1,000 mL fruit circulation jacket reactor was installed by attaching a stirrer, a nitrogen injection device, a dropping funnel, a temperature controller, and a condenser thereto, charged with 93.11 g of N-methylpyrrolidone (NMP) while filling it with nitrogen, and the mixture was maintained at 25° C. while stirring. Then, 20 g of 4,4′-oxydianiline was added thereto and the mixture was stirred until it was completely dissolved, and 3.28 g of 5-norbornen-2,3-dicarboxylic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 40 g of ethanol was added thereto and maintained for 1 hour while stirring. Then, 1,417 g of ethanol was added to the filtered solution using a filter paper to precipitate a solid. This solid was dissolved in 56.68 g of THE and added dropwise to 6,802 g of distilled water to cause precipitation. The solid obtained here was washed twice with distilled water and then dried under vacuum at 25° C. for 48 hours to obtain copolymerized polyimide precursor powder.

### Synthesis Example 10

(Solution A) A 500 mL fruit circulation jacket reactor was installed by attaching a stirrer, a nitrogen injection device, a dropping funnel, a temperature controller, and a condenser thereto, charged with 149.04 g of N-methylpyrrolidone (NMP) while filling it with nitrogen. Then, 8.01 g of 4,4′-oxydiphthalic anhydride and 7.60 g of 3,3′,4,4′-biphenyltetracarboxylic dianhydride were added thereto and the mixture was maintained at 35° C. while stirring. 14.89 g of 4-hydroxybutyl acrylate was added thereto and reacted while slowly adding 16.75 g of pyridine thereto. Thereafter, a solution, in which 21.31 g of N,N′-dicyclohexylcarbodiimide and 42.62 g of γ-butyrolactone were mixed, was slowly added thereto dropwise and stirred for 3 hours while maintaining the internal temperature of the reactor where the reaction was in progress at −10° C.

(Solution B) A 1,000 mL fruit circulation jacket reactor was installed by attaching a stirrer, a nitrogen injection device, a dropping funnel, a temperature controller, and a condenser thereto, charged with 87.54 g of N-methylpyrrolidone (NMP) while filling it with nitrogen, and the mixture was maintained at 25° C. while stirring. Then, 20 g of 9,9-bis(4-aminophenyl) fluorene was added thereto and the mixture was stirred until it was completely dissolved, and 1.88 g of 5-norbornen-2,3-dicarboxylic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 40 g of ethanol was added thereto and maintained for 1 hour while stirring. Then, 917 g of ethanol was added to the filtered solution using a filter paper to precipitate a solid. This solid was dissolved in 36.70 g of THE and added dropwise to 6,802 g of distilled water to cause precipitation. The solid obtained here was washed twice with distilled water and then dried under vacuum at 25° C. for 48 hours to obtain copolymerized polyimide precursor powder.

### Synthesis Example 11

(Solution A) A 500 mL fruit circulation jacket reactor was installed by attaching a stirrer, a nitrogen injection device, a dropping funnel, a temperature controller, and a condenser thereto, charged with 176.52 g of N-methylpyrrolidone (NMP) while filling it with nitrogen. Then, 9.55 g of 4,4′-oxydiphthalic anhydride and 9.06 g of 3,3′,4,4′-biphenyltetracarboxylic dianhydride were added thereto and the mixture was maintained at 35° C. while stirring. 17.75 g of 4-hydroxybutyl acrylate was added thereto and reacted while slowly adding 19.97 g of pyridine thereto. Thereafter, a solution, in which 25.41 g of N,N′-dicyclohexylcarbodiimide and 50.80 g of γ-butyrolactone were mixed, was slowly added thereto dropwise and stirred for 3 hours while maintaining the internal temperature of the reactor where the reaction was in progress at −10° C.

(Solution B) A 500 mL fruit circulation jacket reactor was installed by attaching a stirrer, a nitrogen injection device, a dropping funnel, a temperature controller, and a condenser thereto, charged with 88.98 g of N-methylpyrrolidone (NMP) while filling it with nitrogen, and the mixture was maintained at 25° C. while stirring. Then, 20 g of 1,4-bis(4-aminophenoxy)benzene was added thereto and the mixture was stirred until it was completely dissolved, and 2.25 g of 5-norbornen-2,3-dicarboxylic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 40 g of ethanol was added thereto and maintained for 1 hour while stirring. Then, 1,045 g of ethanol was added to the filtered solution using a filter paper to precipitate a solid. This solid was dissolved in 56.68 g of THE and added dropwise to 5,019 g of distilled water to cause precipitation. The solid obtained here was washed twice with distilled water and then dried under vacuum at 25° C. for 48 hours to obtain copolymerized polyimide precursor powder.

### Synthesis Example 12

(Solution A) A 500 mL fruit circulation jacket reactor was installed by attaching a stirrer, a nitrogen injection device, a dropping funnel, a temperature controller, and a condenser thereto, charged with 118.6 g of N-methylpyrrolidone (NMP) while filling it with nitrogen. Then, 4.76 g of 4,4′-oxydiphthalic anhydride and 8.38 g of 3,3′,4,4′-biphenyltetracarboxylic dianhydride were added thereto and the mixture was maintained at 35° C. while stirring. 12.64 g of 4-hydroxybutyl acrylate was added thereto and reacted while slowly adding 14.22 g of pyridine thereto. Thereafter, a solution, in which 18.09 g of N,N′-dicyclohexylcarbodiimide and 36.18 g of γ-butyrolactone were mixed, was slowly added thereto dropwise and stirred for 3 hours while maintaining the internal temperature of the reactor where the reaction was in progress at −10° C.

(Solution B) A 1,000 mL fruit circulation jacket reactor was installed by attaching a stirrer, a nitrogen injection device, a dropping funnel, a temperature controller, and a condenser thereto, charged with 86.40 g of N-methylpyrrolidone (NMP) while filling it with nitrogen, and the mixture was maintained at 25° C. while stirring. Then, 20 g of 2,2′-bis(4-aminophenoxy)phenylpropane was added thereto and the mixture was stirred until it was completely dissolved, and 1.60 g of 5-norbornen-2,3-dicarboxylic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then 40 g of ethanol was added thereto and maintained for 1 hour while stirring. Then, 815 g of ethanol was added to the filtered solution using a filter paper to precipitate a solid. This solid was dissolved in 32.61 g of THE and added dropwise to 3,913 g of distilled water to cause precipitation. The solid obtained here was washed twice with distilled water and then dried under vacuum at 25° C. for 48 hours to obtain copolymerized polyimide precursor powder.

### Synthesis Example 13

(Solution A) A 500 mL fruit circulation jacket reactor was installed by attaching a stirrer, a nitrogen injection device, a dropping funnel, a temperature controller, and a condenser thereto, charged with 141.87 g of N-methylpyrrolidone (NMP) while filling it with nitrogen. Then, 22.22 g of 3,3′,4,4′-benzophenonetetracarboxylic anhydride was added thereto and the mixture was maintained at 25° C. while stirring. 19.86 g of 4-hydroxybutyl acrylate was added thereto and reacted while slowly adding 11.17 g of pyridine thereto. Thereafter, a solution, in which 35.54 g of N,N′-dicyclohexylcarbodiimide and 71.07 g of γ-butyrolactone were mixed, was slowly added thereto dropwise and stirred for 3 hours while maintaining the internal temperature of the reactor where the reaction was in progress at −10° C.

(Solution B) A 500 mL fruit circulation jacket reactor was installed by attaching a stirrer, a nitrogen injection device, a dropping funnel, a temperature controller, and a condenser thereto, charged with 61.41 g of N-methylpyrrolidone (NMP) while filling it with nitrogen, and the mixture was maintained at 25° C. while stirring. Then, 15 g of 3,3′-dimethylbenzidine was added thereto and the mixture was stirred until it was completely dissolved, and 0.35 g of succinic anhydride was added thereto and reacted for 5 hours, and then the internal temperature was cooled to −10° C. and maintained thereat.

(Polymerization Reaction) Solution A was added dropwise to solution B, which was maintained at −10° C., using a quantitative pump while stirring for 1 hour. Then, the temperature was raised to 25° C. over 1 hour, the reaction was maintained for 2 hours, and then added dropwise to 1,563 g of distilled water and 782 g of ethanol to precipitate. The solid obtained here was washed twice with distilled water and then dried under vacuum at 25° C. for 48 hours to obtain copolymerized polyimide precursor powder.

### Synthesis Example 14

(Solution A) A 500 mL fruit circulation jacket reactor was installed by attaching a stirrer, a nitrogen injection device, a dropping funnel, a temperature controller, and a condenser thereto, charged with 281.4 g of N-methylpyrrolidone (NMP) while filling it with nitrogen. Then, 10.84 g of 4,4′-oxydiphthalic anhydride and 19.10 g of 3,3′,4,4′-biphenyltetracarboxylic dianhydride were added thereto and the mixture was maintained at 35° C. while stirring. 28.80 g of 4-hydroxybutyl acrylate was added thereto and reacted while slowly adding 32.39 g of pyridine thereto. Thereafter, a solution, in which 41.21 g of N,N′-dicyclohexylcarbodiimide and 84.42 g of γ-butyrolactone were mixed, was slowly added thereto dropwise and stirred for 3 hours. Thereafter, 80 g of N-methylpyrrolidone (NMP) was added to the reactor, 20 g of 4,4′-oxydianiline was added in portions over 1 hour, and the mixture was stirred until it was completely dissolved, and reacted for 5 hours.

Then, the temperature was raised to 25° C. over 1 hour, the reaction was maintained for 2 hours, and then 40 g of ethanol was added thereto and maintained for 1 hour while stirring. Then, 1,492 g of ethanol was added to the filtered solution using a filter paper to precipitate a solid. This solid was dissolved in 59.69 g of THF and added dropwise to 7,162 g of distilled water to cause precipitation. The solid obtained here was washed twice with distilled water and then dried under vacuum at 25° C. for 48 hours to obtain copolymerized polyimide precursor powder.

### (Preparation Example 1) Preparation of Negative Photosensitive Resin Composition

14.88 g of the polyimide precursor obtained in Synthesis Examples 1 to 7, 0.45 g of PBG-304 (Tronly), 7.3 g of Miramer, 0.015 g of F-563 (DIC Corporation), 1.5 g of KBM-573 (Shinetsu Silicone), and 1.0 g of 1,4-bis(methoxymethyl)benzene were stirred at room temperature together with 53.4 g of propylene glycol methyl ether acetate (PGMEA). Then, the photosensitive resin compositions were prepared by filtering the compositions three times to remove impurities.

The photosensitive resin compositions were prepared according to the compositions shown in Table 1 below.

TABLE 1

| | Polyimide | | | | | 1,4- | |
|---|---|---|---|---|---|---|---|
| | Precursor | PBG- | MIRAMER | | KBM- | bis(methoxymethyl) | |
| | Copolymer | 304 | M600 | F-563 | 573 | benzene | PGMEA |
| Example 1 | Synthesis | 0.60% | 5.69% | 0.02% | 1.99% | 1.32% | 70.69% |
| | Example 1 | | | | | | |
| | 19.70% | | | | | | |
| Example 2 | Synthesis | 0.60% | 5.69% | 0.02% | 1.99% | 1.32% | 70.69% |
| | Example 2 | | | | | | |
| | 19.70% | | | | | | |
| Example 3 | Synthesis | 0.60% | 5.69% | 0.02% | 1.99% | 1.32% | 70.69% |
| | Example 3 | | | | | | |
| | 19.70% | | | | | | |
| Example 4 | Synthesis | 0.60% | 5.69% | 0.02% | 1.99% | 1.32% | 70.69% |
| | Example 4 | | | | | | |
| | 19.70% | | | | | | |
| Example 5 | Synthesis | 0.60% | 5.69% | 0.02% | 1.99% | 1.32% | 70.69% |
| | Example 5 | | | | | | |
| | 19.70% | | | | | | |
| Example 6 | Synthesis | 0.60% | 5.69% | 0.02% | 1.99% | 1.32% | 70.69% |
| | Example 6 | | | | | | |
| | 19.70% | | | | | | |
| Example 7 | Synthesis | 0.60% | 5.69% | 0.02% | 1.99% | 1.32% | 70.69% |
| | Example 7 | | | | | | |
| | 19.70% | | | | | | |
| Example 8 | Synthesis | 0.60% | 5.69% | 0.02% | 1.99% | 1.32% | 70.69% |
| | Example 8 | | | | | | |
| | 19.70% | | | | | | |
| Example 9 | Synthesis | 0.60% | 5.69% | 0.02% | 1.99% | 1.32% | 70.69% |
| | Example 9 | | | | | | |
| | 19.70% | | | | | | |
| Example 10 | Synthesis | 0.60% | 5.69% | 0.02% | 1.99% | 1.32% | 70.69% |
| | Example 10 | | | | | | |
| | 19.70% | | | | | | |
| Example 11 | Synthesis | 0.60% | 5.69% | 0.02% | 1.99% | 1.32% | 70.69% |
| | Example 11 | | | | | | |
| | 19.70% | | | | | | |
| Example 12 | Synthesis | 0.60% | 5.69% | 0.02% | 1.99% | 1.32% | 70.69% |
| | Example 12 | | | | | | |
| | 19.70% | | | | | | |
| Comparative | Synthesis | 0.60% | 5.69% | 0.02% | 1.99% | 1.32% | 70.69% |
| Example1 | Example 13 | | | | | | |
| | 19.70% | | | | | | |
| Comparative | Synthesis | 0.60% | 5.69% | 0.02% | 1.99% | 1.32% | 70.69% |
| Example1 | Example 14 | | | | | | |
| | 19.70% | | | | | | |

The method for preparing a specimen for a universal material testing machine (UTM) using the negative photosensitive resin compositions is as follows.

### (1) Application and Coating Steps

A photosensitive resin composition is a low-viscosity liquid sample, and a spin coater or slit coater is used in order to coat the photosensitive resin composition to a certain thickness after applying the photosensitive resin composition onto a substrate. The spin coater has an advantage in that the flatness deviation in the area decreases although the thickness is decreased as the number of revolutions increases, and a slit coater is preferable to a spin coater in order to coat the photosensitive resin composition on a large area substrate. Due to the solvent remaining after coating, the surface may have fluidity, and there is a disadvantage in that flatness deteriorates due to this, and in order to overcome the disadvantage, the fluidity on the surface is lowered by removing a portion of the solvent using vacuum chamber dry (VCD).

### (2) Prebaking Step

This is a process of removing a portion of the solvent contained in the coating film by heating the coated substrate with a hot plate or an oven at a predetermined temperature and time. When the surface or core part of the coating film is not dried, photomask contamination occurs during exposure in the next process, and when irradiated with ultraviolet light, the exposed portion does not cure well, and the pattern is not formed and removed in the development process due to non-curing.

### (3) Exposure Step

This is a process of curing a formed film by irradiating active rays (ultraviolet rays) using a photomask in which a pattern is formed when the prebaking process is finished. Types of lamps that generate active rays include LED lamps or metal (mercury) lamps, and wavelengths include g-line (436 nm), h-line (405 nm), i-line (365 nm), and deep UV (<260 nm), which can be used individually or in a mixed form.

### (4) Development Step

When irradiating active rays in the exposure step, the formed film is divided into an exposed portion and a non-exposed portion by the photo mask, and in the case of the positive type, the exposed portion is melted by a developer, and the non-exposed portion withstands the developer and the pattern remains. In the case of the negative type, the exposed portion is cured and has resistance to the developer, and the non-exposed portion is developed. The composition of the present disclosure is a negative type and divided into the exposed portion (curing) and the non-exposed portion (development) to form a pattern.

### (5) Post-Heat Treatment Step

This is a process of removing the remaining solvent and fume by heating the developed substrate at a high temperature of 210° C. or higher. When the solvent and fume are not completely removed in the relevant process, outgases are generated in the post-heat treatment process to affect the device so that dark spots or pixel shrinkage may be affected due to the same.

### (6) Peeling of Specimen

In order to obtain a UTM specimen without damage from a substrate that has completed the post-heat treatment step, the substrate was dipped into a 2% hydrofluoric acid solution at 23±2° C. for a certain period of time (minutes), and then the separated specimen was washed with ultrapure water (DI water) and then dried in a vacuum chamber at room temperature to obtain a specimen for UTM.

### (7) UTM Measurement

The UTM specimens of Examples and Comparative Examples obtained in the peeling step of the specimens were measured for tensile strength and elongation using QM100S, a universal material testing machine from QMESYS. The measurement conditions were as follows: measurement temperature (25° C.), tensile speed (5 mm/min), and gauge distance (20 mm).

TABLE 2

| | | Hole | | |
|---|---|---|---|---|
| | | Pattern | Elongation | Tensile |
| | Residue After | Accuracy | Rate | Strength |
| | Development | (30 μm) | (%) | (MPa) |
| Example 1 | X | 29.6876 | 63.1 ± 0.2 | 4.41 ± 0.1 |
| Example 2 | X | 29.6763 | 67.1 ± 0.3 | 5.58 ± 0.2 |
| Example 3 | X | 29.6956 | 62.2 ± 0.3 | 4.50 ± 0.1 |
| Example 4 | X | 29.8950 | 62.9 ± 0.4 | 4.43 ± 0.3 |
| Example 5 | X | 29.8754 | 67.4 ± 0.2 | 5.52 ± 0.2 |
| Example 6 | X | 29.8465 | 63.9 ± 0.4 | 4.58 ± 0.4 |
| Example 7 | X | 29.8976 | 68.7 ± 0.2 | 4.41 ± 0.1 |
| Example 8 | X | 29.9763 | 66.4 ± 0.3 | 4.68 ± 0.2 |
| Example 9 | X | 29.9456 | 62.2 ± 0.3 | 5.80 ± 0.1 |
| Example 10 | X | 29.8950 | 66.7 ± 0.4 | 5.53 ± 0.3 |
| Example 11 | X | 29.8754 | 67.4 ± 0.2 | 4.80 ± 0.2 |
| Example 12 | X | 29.8465 | 66.9 ± 0.4 | 4.98 ± 0.4 |
| Comparative | X | 29.6540 | 51.6 ± 0.3 | 3.16 ± 0.3 |
| Example1 | | | | |
| Comparative | X | 29.8740 | 51.6 ± 0.3 | 3.16 ± 0.3 |
| Example2 | | | | |

As a result of the development test disclosed in Table 2 above, it was confirmed that none of Examples 1 to 12 and Comparative Examples 1 and 2 exhibited the phenomenon of showing residue remaining after development. As a result of confirming the accuracy of pattern implementation using a 30 μm hole mask, it was found that in both Example 1 to Example 6 and Comparative Example 1, the pattern was accurately implemented with an error within 0.4 μm, and that in both Example 7 to Example 12 and Comparative Example 2, the pattern was implemented accurately with an error within 0.2 μm.

According to the UTM measurement results, the tensile strength of Examples 1 to 6 in Table 1 above was 4.41 MPa or more, and that of Comparative Example 1 was measured to be 3.16 MPa. Additionally, the elongation rate was 62% or higher in Examples 1 to 6, and that of Comparative Example 1 was measured at 51.6%, thereby confirming that the introduction of a reactive group at the terminal of the polyimide precursor according to the present disclosure is effective in improving tensile strength and elongation rate.

The present disclosure is not limited to these Examples and may be prepared in various different forms.

The above description is merely illustrative of the present disclosure, and those skilled in the art to which the present disclosure pertains will be able to make various modifications without departing from the essential characteristics of the present disclosure.

Accordingly, the embodiments disclosed in this specification are for illustrative purposes only and are not intended to limit the present disclosure, and the spirit and scope of the present disclosure are not limited by these embodiments. The scope of protection of the present disclosure should be interpreted in accordance with the claims, and all technologies within the scope equivalent thereto should be interpreted as being included in the scope of rights of the present disclosure.

What is claimed is:

1. A polyimide precursor comprising a reactive end group represented by Formula Q below: 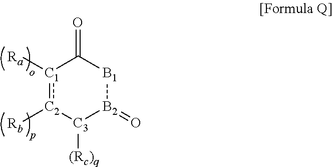
wherein in Formula Q above,
1) Rₐ to R_{c} are each independently hydrogen; deuterium; a hydroxy group; a C₆₋₃₀ aryl group; a C₂₋₃₀ heterocyclic group comprising at least one heteroatom among O, N, S, Si, and P;
a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alkynyl group; a C₁₋₃₀ alkoxy group; a C₆₋₃₀ aryloxy group; a C₁₋₃₀ hydroxyacrylic group; a C₁₋₃₀ hydroxymethacrylic group; a fluorenyl group; a carbonyl group; an ether group; a carboxyl group; or a C₁₋₃₀ alkoxycarbonyl group; or neighboring groups of Rₐ to R_{c} form a ring;
2) C₁ and C₂ are carbon; and the bond connecting C₁ and C₂ is a single bond or double bond,
3) when the bond connecting C₁ and C₂ is a single bond, o and p are each independently an integer of 1 or 2; and when the double dotted line connecting C₁ and C₂ is a double bond, o and p are each independently an integer of 1,
4) C₃ is carbon or a direct bond of C₂—B₂,
5) when C₃ is carbon, q is an integer of 1 or 2,
6) the dotted line connecting B₁ and B₂ is a non-existent bond or single bond,
7) when the dotted line connecting B₁ and B₂ is absent, B₁ is hydrogen; deuterium; a hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a C₁₋₂₀ hydroxyacrylic group; a C₁₋₂₀ hydroxymethacrylic group; a fluorenyl group; a carbonyl group; an ether group; a carboxyl group; or a C₁₋₂₀ alkoxycarbonyl group; and B₂ is carbon connected to a polyimide repeating unit;
8) when the dotted line connecting B₁ and B₂ is a single bond, B₁ is nitrogen connected to a polyimide repeating unit; and B₂ is carbon, and
9) the rings formed by binding between Rₐ to R_{c} and the neighboring groups are each further substituted with at least one substituent selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₈₋₃₀ arylalkenyl group; and a combination thereof, or form a ring between the neighboring substituents.

2. The polyimide precursor of claim 1, wherein the polyimide precursor comprises a repeating unit selected from the group consisting of Formula 1-1 below, Formula 1-2 below, and a combination thereof: 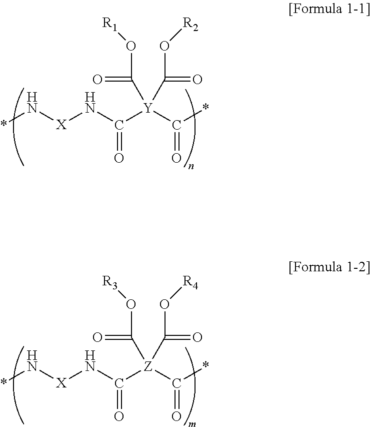
wherein in Formula 1-1 and Formula 1-2 above,
1) * represents a repeating unit or a part in which a bond is connected to the reactive end group represented by Formula Q in claim 1,
2) R₁ and R₄ are Formula 2 below,
3) X is Formula 3 below,
4) m and n are an integer of 1 to 1,000, 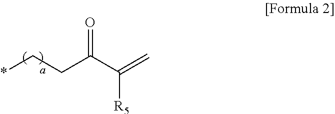
wherein in Formula 2 above,
5) * is a part in which a bond is connected,
6) a is an integer of 1 to 30,
7) R₅ is hydrogen or a methyl group,
8) Y is selected from the group consisting of a C₆₋₃₀ arylene; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkylene group; a C₁₋₂₀ cycloalkylene group; a C₂₋₂₀ alkenylene group; a C₃₋₂₀ cycloalkenylene group; a C₂₋₂₀ alkynylene group; a C₃₋₂₀ cycloalkynylene group; Formula 3 below; and a combination thereof,
9) Z is selected from the group consisting of a C₆₋₃₀ arylene; a C₂₋₃₀ heterocyclic group including at least one heteroatom among O, N, S, Si, and P; a fused ring group of a C₆₋₃₀ aliphatic ring and a C₆₋₃₀ aromatic ring; a C₁₋₂₀ alkylene group; a C₁₋₂₀ cycloalkylene group; a C₂₋₂₀ alkenylene group; a C₃₋₂₀ cycloalkenylene group; a C₂₋₂₀ alkynylene group; a C₃₋₂₀ cycloalkynylene group; Formula 3 below; and a combination thereof, 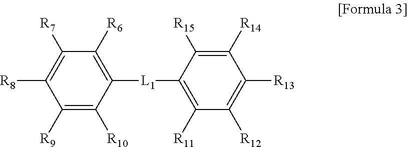
10) L₁ is selected from the group consisting of a single bond, —CH₂—, —CH₂CH₂—, —CH₂OCH₂—, —CH(CH₃)—, —C(CH₃)₂—, —O—, —CH(CF₃)—, —C(CF₃)₂—, —S—, —SO₂—, Si(CH₃)₂—, —C₆H₄—, —OC₆H₄O—, —CO—, —NHCO—, and —COO—,
11) two of R₆ to R₁₅ are parts connected with an amide group of Formula 1-1 or Formula 1-2 above,
12) the remaining R₆ to R₁₅ excluding the connection parts above are each independently hydrogen; deuterium; a hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a fluorenyl group; a carbonyl group; an ether group; a carboxyl group; or a C₁₋₂₀ alkoxycarbonyl group; or neighboring R⁶ and R¹⁵; and R¹⁰ and R¹¹ form a ring, and
13) the rings formed by binding between Y, Z, R₆ to R₁₅, and the neighboring groups are each further substituted with at least one substituent selected from the group consisting of deuterium; halogen; a silane group substituted or unsubstituted with a C₁₋₃₀ alkyl group or C₆₋₃₀ aryl group; a siloxane group; a boron group; a germanium group; a cyano group; an amino group; a nitro group; a C₁₋₃₀ alkylthio group; a C₁₋₃₀ alkoxy group; a C₆₋₃₀ arylalkoxy group; a C₁₋₃₀ alkyl group; a C₂₋₃₀ alkenyl group; a C₂₋₃₀ alkynyl group; a C₆₋₃₀ aryl group; a C₆₋₃₀ aryl group substituted with deuterium; a fluorenyl group; a C₂₋₃₀ heterocyclic group comprising at least one heteroatom among O, N, S, Si, and P; a C₃₋₃₀ alicyclic group; a C₇₋₃₀ arylalkyl group; a C₈₋₃₀ arylalkenyl group; and a combination thereof, or form a ring between the neighboring substituents.

3. The polyimide precursor of claim 1, wherein the compound represented by Formula Q above comprises the following compounds represented by Q-1 to Q-6 below: 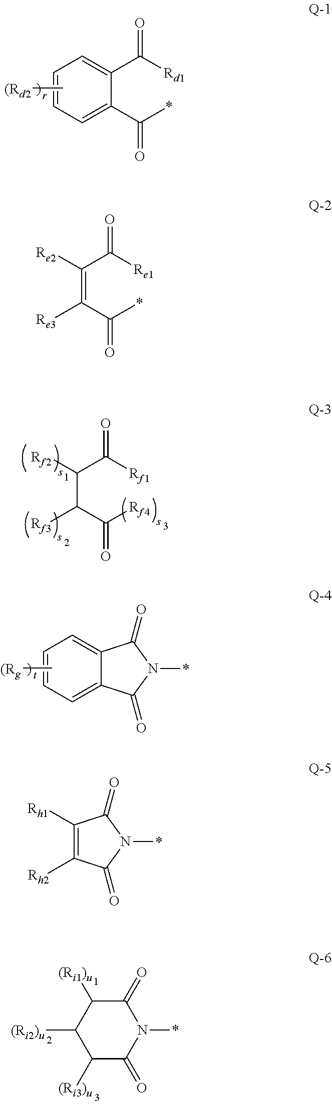
in Formulas Q-1 to Q-6 above,
1) R_{d1}, R_{d2}, Rₑ₁ to Rₑ₃, R_{f1} to R_{f4}, R_{g}, Rₕ₁, Rₕ₂, and Rᵢ₁ to Rᵢ₃ are each independently hydrogen; deuterium; a hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₃₀ alkyl group; a C₂₋₃₀ alkenyl group; a C₂₋₃₀ alknyl group; a C₁₋₃₀ alkoxy group; a C₆₋₃₀ aryloxy group; a C₁₋₃₀ hydroxyacrylic group; a C₁₋₃₀ hydroxymethacrylic group; a fluorenyl group; a carbonyl group; an ether group; a carboxyl group; or a C₁₋₃₀ alkoxycarbonyl group,
2) r and t are an integer of 1 to 4,
3) s₁, s₂, and u₁ and u₃ are each independently an integer of 1 or 2, and
4) * is a part in which the bond is connected.

4. The polyimide precursor of claim 1, wherein the compound represented by Formula Q above comprises the following compounds represented by Q-7 to Q-10 below:
<Formulas Q-7 to Q-10> 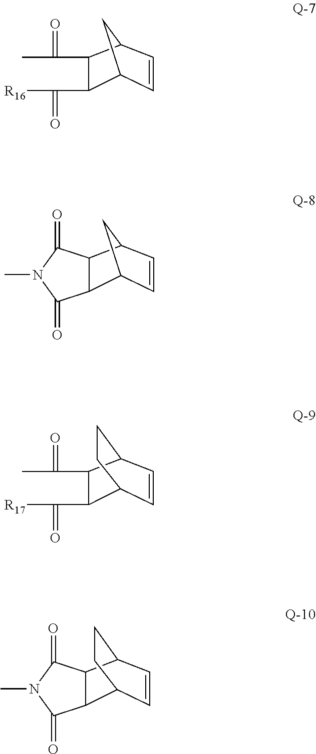
wherein in Formulas Q-7 to Q-10 above,
R₁₆ to R₁₈ are each independently hydrogen; deuterium; a hydroxy group; a C₆₋₃₀ aryl group; a C₂₋₃₀ heterocyclic group comprising at least one heteroatom among O, N, S, Si, and P; a fused ring group of a C₆₋₃₀ aliphatic ring and a C₆₋₃₀ aromatic ring; a C₁₋₂₀ alkyl group; a C₂₋₂₀ alkenyl group; a C₂₋₂₀ alknyl group; a C₁₋₂₀ alkoxy group; a C₆₋₃₀ aryloxy group; a C₁₋₂₀ hydroxyacrylic group; a C₁₋₂₀ hydroxymethacrylic group; a fluorenyl group; a carbonyl group; an ether group; a carboxyl group; or a C₁₋₂₀ alkoxycarbonyl group, and
wherein one formula selected from Formulas Q-7 to Q-10 above or a formula selected from the group consisting of combinations thereof is connected to the end of the precursor by an amide or imide bond.

5. The polyimide precursor of claim 1, wherein the polyimide precursor comprises at least one among a diamine monomer; a dianhydride monomer; and an anhydride monomer.

6. The polyimide precursor of claim 1, wherein the weight average molecular weight of the polyimide precursor is 5,000 g/mol to 40,000 g/mol.

7. A polyimide composition comprising the polyimide precursor of claim 6; a photoinitiator; a reactive unsaturated compound; a solvent; and an additive.

8. The polyimide composition of claim 7, wherein the polyimide precursor is contained in an amount of 5 wt % to 50 wt % based on the total amount of the composition.

9. The polyimide composition of claim 7, wherein the photoinitiator is contained in an amount of 0.01 wt % to 10 wt % based on the total amount of the composition.

10. The polyimide composition of claim 7, wherein the reactive unsaturated compound is contained in an amount of 1 wt % to 40 wt % based on the total amount of the composition.

11. The polyimide composition of claim 7, wherein the solvent is contained in an amount of 50 wt % to 95 wt % based on the total amount of the composition.

12. The polyimide composition of claim 7, wherein the additive is contained in an amount of 0.001 wt % to 10 wt % based on the total amount of the composition.

13. A pattern or film prepared from the polyimide composition of claim 7.

14. A semiconductor device prepared using the pattern or film of claim 13.

15. A display device prepared using the pattern or film of claim 13.

16. An electronic device comprising the display device of claim 15; and a control unit driving the same.
